(19) United States
(12) Patent Application Publication
(10) Pub. No.: US 2025/0385451 A1
(43) Pub. Date: Dec. 18, 2025

(54) MEMORY SYSTEM AND METHOD OF OPERATION

(71) Applicant: Dell Products L.P., Round Rock, TX (US)

(72) Inventors: JORDAN CHIN, Austin, TX (US); WILLIAM ANDREW SMITH, Round Rock, TX (US); CORY D. PATE, Leander, TX (US)

(21) Appl. No.: 18/745,009

(22) Filed: Jun. 17, 2024

(51) Int. Cl. H01R 12/72; G11C 7/10

(52) U.S. Cl. CPC H01R 12/721; G11C 7/1048; G11C 7/1084; H05K 2201/09409; H05K 2201/10159; H05K 2201/10212; H05K 2201/10325

(57) ABSTRACT

A data processing system is disclosed. The data processing system may include a processor, memory module, and circuit board. The circuit board may include a first socket for the processor. The circuit board may include a second socket for the memory module. The circuit board may also include a first physical memory channel interconnecting a first portion of the first socket and a first portion of the second socket. The circuit board may additionally include a second physical memory channel interconnecting a second portion of the first socket and a second portion of the second socket.

### FIELD OF THE DISCLOSURE

Embodiments disclosed herein generally relate to data processing systems. More particularly, embodiments disclosed herein relate to memory systems for data processing systems.

### BACKGROUND

Computing devices may provide various types of computer implemented services. To provide the computer-implemented services, computing devices may include various type of hardware devices such as, for example, processors, memory modules, and storage devices. These hardware components may need to be positioned with one another to provide their respective functions. Similarly, various components devices may be aggregated together to form a computing system.

### BRIEF DESCRIPTION OF THE DRAWINGS

Embodiments disclosed herein are illustrated by way of example and not limitation in the figures of the accompanying drawings in which like references indicate similar elements.

FIG. 1 shows a diagram illustrating a data processing system in accordance with an embodiment.

FIG. 2 shows a top view diagram illustrating a portion of the data processing system in accordance with an embodiment.

FIG. 3 shows an isometric view diagram of a socket and memory modules in accordance with an embodiment.

FIG. 4 shows a first front view diagram of a memory module in accordance with an embodiment.

FIG. 5 shows a second front view diagram of a memory module in accordance with an embodiment.

FIG. 6 shows a third front view diagram of a memory module in accordance with an embodiment.

FIG. 7 shows a first side view diagram illustrating a memory module and socket in accordance with an embodiment.

FIG. 8 shows a second side view diagram illustrating a memory module and socket in accordance with an embodiment.

FIG. 9 shows a flow diagram illustrating a method in accordance with an embodiment.

FIG. 10 shows a block diagram illustrating a data processing system in accordance with an embodiment.

### DETAILED DESCRIPTION

Various embodiments will be described with reference to details discussed below, and the accompanying drawings will illustrate the various embodiments. The following description and drawings are illustrative of the embodiment disclosed herein and are not to be construed as limiting the disclosed embodiments. Numerous specific details are described to provide a thorough understanding of various embodiments. However, in certain instances, well-known or conventional details are not described in order to provide a concise discussion of embodiments disclosed herein.

Reference in the specification to “one embodiment” or “an embodiment” means that a particular feature, structure, or characteristic described in conjunction with the embodiment can be included in at least one embodiment disclosed herein. The appearances of the phrases “in one embodiment”, “an embodiment”, and similar recitations in various places in the specification do not necessarily all refer to the same embodiment.

In general, embodiments disclosed herein relate to systems and methods for providing computer implemented services. To provide computer implemented services, data processing systems may include hardware components. The hardware components may consume power, and provide the computer implemented services using the power.

During performance of the computer implemented services, data may be transmitted between various components such as processors and memory modules. The data may be transmitted via multiple memory channels to a single memory module.

The memory module may include stacked memory devices to facilitate servicing of the storage requests obtained via the multiple memory channels. By using multiple memory channels and stacked memory devices (and/or stacked dies therein), the density of the memory and bandwidth to the memory may be greatly increased. The increased bandwidth and component density may enable other devices to be positioned where memory modules normally reside without negatively impacting the memory performance of data processing systems.

In an embodiment, a data processing system is provided. The data processing system may include a processor; a memory module; and a circuit board including a first socket for the processor; a second socket for the memory module; a first physical memory channel interconnecting a first portion of the first socket and a first portion of the second socket; and a second physical memory channel interconnecting a second portion of the first socket and a second portion of the second socket.

The first physical memory channel and the second physical memory channel may be exclusively used by devices positioned in the second socket.

The second socket may include an interposer; and a plurality of high density fingers adapted to establish electrical contacts with pads of the memory module.

The plurality of high density fingers may be adapted to establish the electrical contacts with the pads in a dual row configuration.

The plurality of high density fingers may be adapted to establish the electrical contacts with the pads in a single row configuration.

The plurality of high density fingers support at least one of 8 gigatransfers per seconds, 10 gigatransfers per second, 20 gigatransfers per second, 25 gigatransfers per second, 30 gigatransfers per second.

The plurality of high density fingers may be adapted to support bandwidth of approximately 1.5 times, 2 times, 2.5 times, 3.5 times, four times that of the Double Data Rate 5 Synchronous Dynamic Random-Access Memory standard.

The memory module may include a carrier including an edge connector including: a first portion adapted to operably connect to the first portion of the second socket; and a second portion adapted to operably connect to the second portion of the socket.

The memory module may also include a first set of memory devices operably connected to the first portion of the edge connector; and a second set of memory devices operably connected to the second portion of the edge connector.

Each memory device of the first set of memory devices may be a multi-die memory device.

The first set of memory devices may be distributed across two sides of the carrier.

The memory module may also include a signal buffer logic adapted to independently manage the first set of memory devices and independently manage the second set of memory devices.

Independently managing the first set of memory devices may include participating in training of a first logical memory channel for the first physical memory channel, the training of the first logical memory channel identifying a communication speed for the first logical memory channel.

The first physical memory channel may include a set of traces positioned on the circuit board.

In an embodiment, a circuit board as discussed above is provided.

In an embodiment, a method of operating a data processing system is provided. The method may include identifying data for storage in a memory module and using at least two channels to store the data in a same memory module.

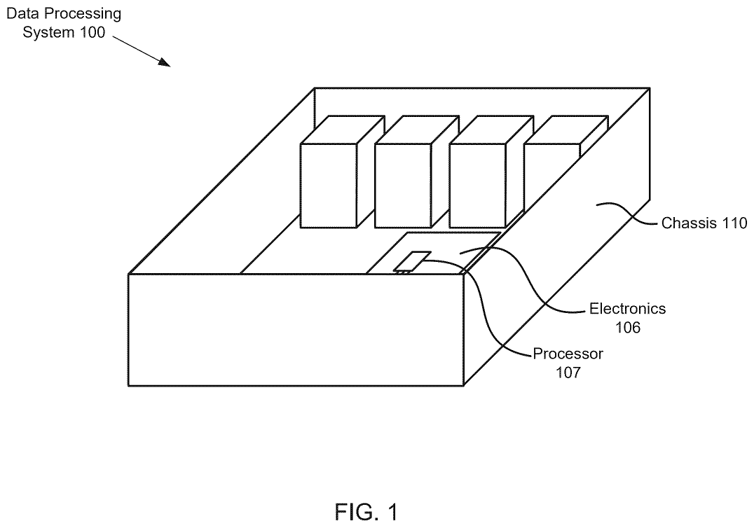

Turning to FIG. 1, a diagram illustrating data processing system 100 in accordance with an embodiment is shown. Data processing system 100 may be used to provide various computer implemented services.

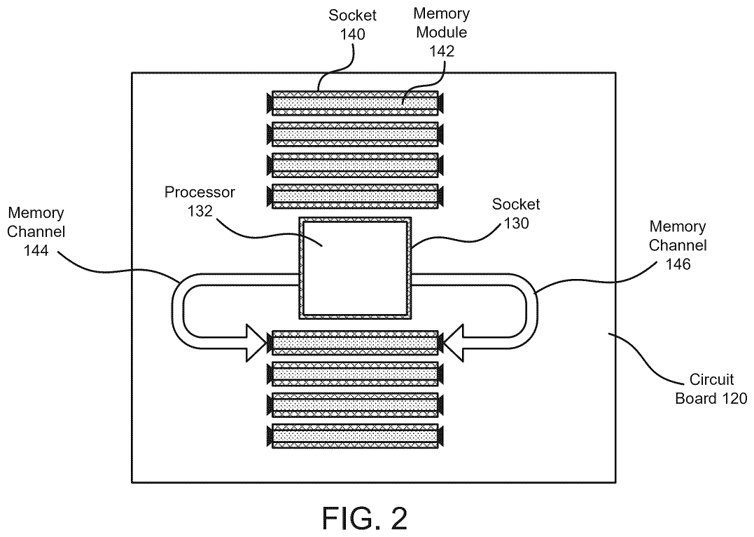

To provide the computer implemented services, data processing system 100 may include a chassis (e.g., 110, illustrated as a rack style but may be other types) and various hardware components (e.g., 106, 107, FIG. 2) positioned therein. The hardware components may include, for example, processors, memory modules, storage devices, special purposes computer devices (e.g., graphics/data processing units), and/or other components.

During operation of the hardware components, various computer implemented services may be provided. The services may include, for example, instant messaging services, database services, inferencing and/or other types of artificial intelligence services, and/or other types of services that may be provided by data processing systems.

To provide the services, the hardware components may perform various tasks. For example, processors may perform computations, memory modules may store data temporarily, storage devices may non-transitorily store data, network interface devices may communicate with remote devices, etc. The number and rate of performance of such tasks by the hardware components may be limited by the types of the components, and interconnections between the components. For example, communications busses may have limited bandwidth and may, therefore, reduce the number of tasks that a particular hardware device may provide per unit time from a maximum amount limited by the architecture of the particular hardware component. Thus, the computer implemented services provided by data processing system 100 may be limited by the hardware components positioned therein.

In general, embodiments disclosed herein relates systems, methods, and devices for providing computer implemented services. To provide the computer implemented services, a data processing system may include hardware components and communication interfaces that enable increased device density.

To facilitate the increased device density, multiple communication interfaces may be utilized with respect to a memory module. The multiple interfaces may facilitate increased communication bandwidth between processors (and/or other hardware components) and the memory modules.

The memory modules include segregated portions of connectors for different communication interfaces, and corresponding memory devices that service input-output requests sent over the communication interfaces. The memory devices may be multi-die devices (e.g., multiple semiconductor devices integrated into a single package, e.g., stacked) to facilitate servicing of the requests (e.g., store/read data).

Sockets used to attach the memory devices to a host circuit board and the memory devices themselves may include features (e.g., numbers/types/positioning of pads/figures) that facilitate communications with bandwidth that is approximately (within 10% of) 1.5 times, 2 times, 2.5 times, 3 times, 3.5 times, or four times that of the Double Data Rate 5 Synchronous Dynamic Random-Access Memory (DDR5 SDRAM) standard. For example, the sockets may include approximately twice the number of pads and the memory devices may include approximately twice the number of pads.

By doing so, embodiments disclosed herein may provide improved communication bandwidth, and reduced system volume required for memory systems. Consequently, additional memory and/or additional capabilities may be provided using the recovered volume.

While illustrated in FIG. 1 with respect to a limited number of specific components in specific positions and orientations, a data processing system may include different number and/or types of components with different positions and/or orientations without departing from embodiments disclosed herein.

Turning to FIG. 2, a top view diagram of a portion of data processing system 100 in accordance with an embodiment is shown. As seen in FIG. 2, various hardware components such as processor 132 and memory module 142 may be positioned therein.

During operation, these components may communicate with one another using electrical signals. For example, various requests from the processor as part of normal program flow may be sent to any number of memory modules. These requests may be for storing of data, reading of stored data, deleting data, applying various special functions (e.g., locking memory space, activating error correction, etc.), and/or other types of requests.

To facilitate such communications, the information may be encoded on electrical signals transmitted between these components. To facilitate transmission of the encoded electrical signals, circuit board 120 may include various features that enable memory channels (e.g., 144, 146) between processor 132 and memory modules to be established.

The memory channels (e.g., may be referred to as communication channels) may each be a 64 bit wide pipeline. The memory channels may be implemented using memory signal buffer logics of processor 132, and traces between a socket (e.g., 130) in which the processor (e.g., 132) is positioned and another socket (e.g., 140) in which a memory module (e.g., 142) is positioned. Socket 130 may, for example, be implemented using a discrete physical component (e.g., a pin grid array, land grid array, or other type of physical device for interconnecting a processor with electrical contacts on a circuit board or other type of carrier), may be integrated (e.g., direct soldering of the processor to the circuit board, in which case the solder and/or any other components that attach the processor to the circuit board or other type of carrier may be considered to be a socket), and/or using other structures.

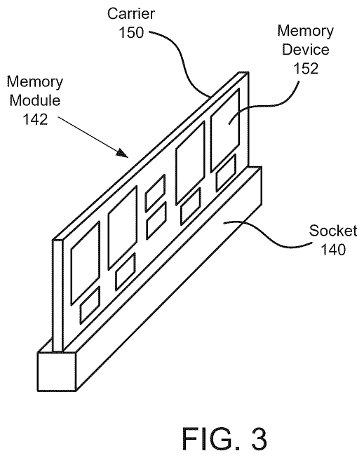

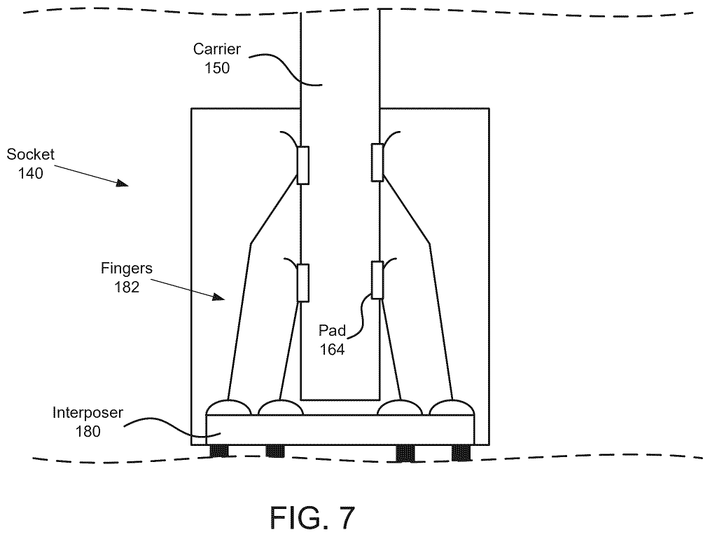

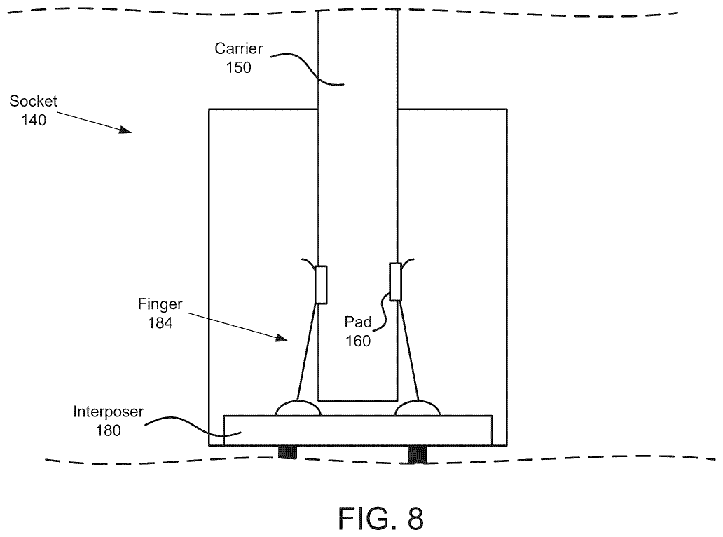

To facilitate improved communication bandwidth, at least one but multiple communication channels may be allocated to a socket (e.g., 140) in which a memory module (e.g., 142) is positioned. The socket may be specially formed to facilitate such interconnection. Refer to FIGS. 7-8 for additional details regarding such sockets. Likewise, the memory modules positioned in the sockets may include features to enable use of multiple memory channels. Refer to FIGS. 3-6 for additional details regarding memory modules.

Returning to the discussion of the memory channels, each memory channel may include any number of metal traces positioned on circuit board 120. Circuit board 120 may be a multilayer circuit board with some metallization positioned in the interior layers of the circuit board.

The traces may interconnect corresponding conductors on socket 130 with conductors on another socket (e.g., 140) in which a memory module is positioned. These traces may facilitate routing and isolation of the electrical signals carried via circuit board 120.

In an embodiment, socket 140 is implemented as a linear socket similar to a dual inline memory module (DIMM) socket. However, socket 140 may include a higher pin count (e.g., more than 556 pins) when compared to DDR2/DDR3 (Double Data Rate) DIMM sockets (e.g., 240 pins) and DDR4/DDR5 DIMM sockets (e.g., 288 pins). Further, socket 140 may have a width to facilitate on pitch spacing of 320 mils (e.g., roughly between 300-340 mils pitch spacing, roughly may mean within 10% of a nominal pitch that is between 280-360 mils). And by virtue of the higher memory capacity of each of memory module 142, half the number of memory modules may be needed for a same memory capacity when compared to DDR2-DDR5 DIMM modules. Thus, the circuit board area may be reduced by approximately 50%.

In an embodiment, socket 130 is implemented using a pin grid array, land grid array, or other type of socket.

While described and illustrated with a select number of components, it will be appreciated that circuit board 120 may host any number and types of components (e.g., other types of devices, chips, discrete components, power components, etc.) without departing from embodiments disclosed herein.

Turning to FIG. 3, an isometric view of socket 140 and memory module 142 in accordance with an embodiment is shown. As seen in FIG. 3, socket 140 may facilitate vertical placement of memory module 142 on circuit board 120. For example, socket 140 may receive an edge connector presented by memory module 142.

Memory module 142 may include carrier 150 on which any number of memory devices (e.g., 152) and/or other devices may be positioned. Carrier 150 may be implemented using circuit board (or other media usable to electrically interconnect various devices), and may facilitate electrical connection of components positioned thereon to components positioned with circuit board 120.

Memory device 152 may be a semi-conductor device for temporarily storing data. For example, memory device 152 may be a memory integrated circuit. The memory integrated circuit may be, for example, a Synchronous dynamic random-access memory (SDRAM) chip or other type of memory device.

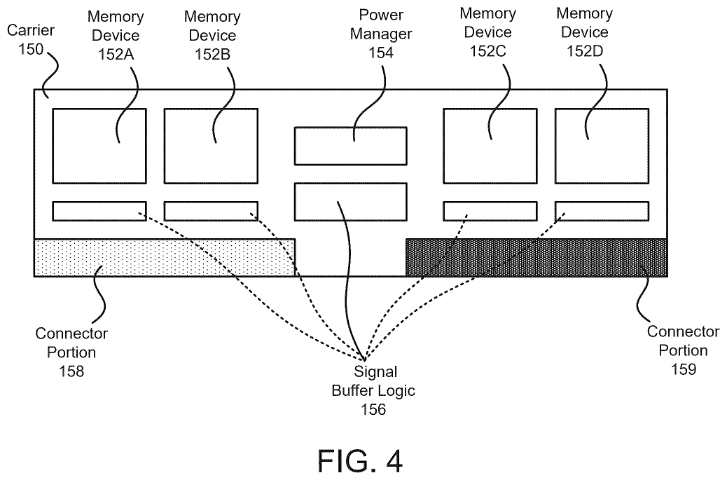

Carrier 150 may host other types of devices in addition to memory device 152. Refer to FIG. 4 for additional details regarding the components hosted by carrier 150.

Carrier 150 may also include an edge connector or other type of connector for connecting some of the traces of carrier 150 to various pins, fingers, and/or other electrical contacts of socket 140. These electrical contacts, in combination with traces of circuit board 120 used to implement memory channels 144-146, may facilitate communications between the devices positioned on carrier 150 and other devices positioned on circuit board 120 such as processor 132.

While illustrated with a limited number of example components, it will be appreciated that sockets and memory modules may include additional, fewer, and/or different components without departing from embodiments disclosed herein. For example, sockets for memory modules may include various retention components (e.g., lock bodies, alignment nubs/pins).

Turning to FIG. 4, a front view diagram of memory module 142 in accordance with an embodiment is shown. As discussed above, two memory channels may be allocated to each socket, and the memory modules hosted by the respective socket.

To facilitate use of these channels, memory module 142 may host a signal buffer logic (e.g., 156), power manager 154, and/or other components. Signal buffer logic 156 may manage establishment of communications on these memory channels. Signal buffer logic 156 may be implemented using one device or multiple devices. For example, in FIG. 4, the dashed lines associating the recitation signal buffer logic 156 with portion of the diagram indicate that the highlighted components may not be present, while the solid line associating the recitation signal buffer logic 156 highlight an example singular component that may be present when signal buffer logic 156 is implemented using a unitary device. The component highlighted using the dashed lines may operate as buffers/signal managers/etc. for corresponding memory devices, when present. Otherwise, this functionality may be performed by the single, unitary signal buffer logic when implemented using a single component.

To facilitate establishment of the communications, signal buffer logic 156 may participate in channel training (e.g., identifying maximum supportable communication bandwidths), channel contention management, channel allocation (e.g., selectively reassignment of channels to different sets of memory devices based on various conditions), and/or other processes to facilitate use of the channels (e.g., checking for signal integrity, communication errors, security, etc.) by the memory devices (e.g., 152A-152D) hosted on carrier 150.

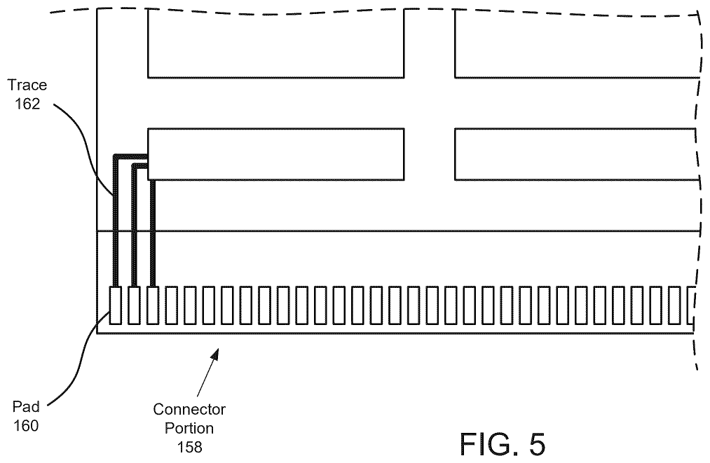

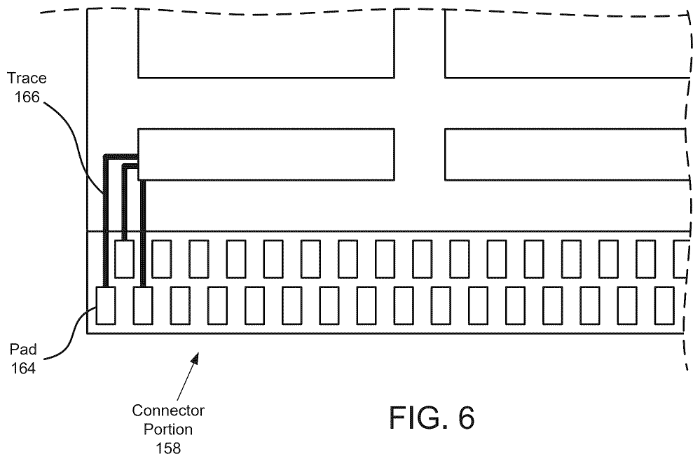

For example, to establish communications with other devices, carrier 150 may include an edge connector. The edge connector may be divided into logical connector portions (e.g., 158, 159). Each connector portion may include pads connector to a corresponding set of memory devices by traces (not shown, refer to FIGS. 5-6).

For example, in FIG. 4, connector portion 158 may be operably connected to memory devices 152A-152B, and may be operably connected to memory channel 144 when inserted in a socket of circuit board 120. Similarly, connector portion 159 may be operably connected to memory devices 152C-152B and may be operably connected to memory channel 146 when inserted in a socket (e.g., 140).

These electrical connections may isolate memory channels 144-146 for exclusive use by memory devices 152A-152D. Thus, the bandwidth available to each of these separate sets of memory devices 152A-152D may be larger than that of DDR2-DDR5 DIMMs.

Power manager 154 may manage use, conditioning, and distribution of power to/by memory devices 152A-152D and/or other components on carrier 150. For example, some number of pads of the connector portions may receive power. The power may not be at desirable/required voltage levels. Power manager 154 may modify the power to meet requirements of users of the power. Likewise, power manager 154 may selectively power/depower various components on carrier 150 over time. For example, if some memory devices are not in use and/or are not anticipated to be in use, then power manager 154 may depower the memory devices. In scenarios in which the memory devices include stacked dies in a package, the individual dies may be selectively powered/depowered.

Turning to FIG. 5, a second front view diagram of a portion of memory module 142 in accordance with an embodiment is shown. The dashed lines in the figure indicate where the partial view is terminated, and the structures depicted within the figure may extend beyond these boundaries.

To provide it functionality, connector portion 158 may include any number of pads (e.g., 160). In FIG. 5, these pads are illustrated in a single row, are of narrow width, and are aligned with one another. To establish electrical contacts, fingers (e.g., metal structures) of socket 140 may make physical contact with the pads. Refer to FIGS. 7-8 for additional details regarding establishing electronical connections between the pads and socket 140.

Each of the pads may be connected to other components on carrier 150 with one or more traces (e.g., 162). The traces may connect the pads, for example, to various chips that may buffer data until it can be written to the memory devices, and/or chips that perform other functions.

While illustrated in FIG. 5 as being in a single row, this topology of the pads may reduce the width of the pads to undesirable levels. For example, such widths may make it more difficult to electrically isolate pads from each other when fingers are present. Alignment mechanisms between the pads and the fingers may be limited and, therefore, may cause fingers to cross the gaps between the pads.

Turning to FIG. 6, a third front view diagram of a portion of memory module 142 in accordance with an embodiment is shown. The dashed lines in the figure indicate where the partial view is terminated, and the structures depicted within the figure may extend beyond these boundaries.

Like the embodiment shown in FIG. 5, to provide it functionality, connector portion 158 may include any number of pads (e.g., 164). In FIG. 6, these pads are illustrated in two rows, are of wider width than those shown in FIG. 5, and the pads in the two rows are offset from one another. To establish electrical contacts, fingers (e.g., metal structures) of socket 140 may make physical contact with the pads similarly as described with respect to FIG. 5. Refer to FIGS. 7-8 for additional details regarding establishing electronical connections between the pads and socket 140.

Each of the pads may be connected to other components on carrier 150 with one or more traces (e.g., 166). The traces may connect the pads, for example, to various chips that may buffer data until it can be written to the memory devices, and/or chips that perform other functions. As seen in FIG. 6, the offsetting and dual rows may allow for the pads to be of larger width while still allowing for traces to run from the pads to the other components. Thus, the likelihood of undesirable shorting or other problems caused by alignment between the memory module and socket 140 may be reduced.

Turning to FIGS. 7 and 8, side view diagrams of the memory module positioned in socket 140 in accordance with embodiments are shown. In FIG. 7, socket 140 is illustrated in a configuration in which it is able to establish electrical contacts with the pads (e.g., 164) shown in FIG. 6, while in FIG. 8 socket 140 is illustrated in a configuration in which it is able to establish electrical contacts with the pads (e.g., 160) shown in FIG. 5.

Turning to FIG. 7, to establish electrical contacts with dual rows of pads, socket 140 may include interposer 180 and fingers 182.

Interposer 180 may include a piece of circuit card or other material usable to route signals from a planar to vertical configuration. For example, posts or other electrical contacts (illustrated in solid black in FIG. 7) may extend downward from interposer 180 and out of a body of socket 140 (e.g., the rectangular outline).

On the surface of interposer 180, any number of fingers 182 may extend upward. Fingers 182 may be metallic structures and may be natively spring loaded and/or loaded by other structures (not shown) to generally press toward a center of socket 140. In FIG. 7, the connector portion of carrier 150 is positioned in socket 140. Consequently, the fingers are illustrated as resting on corresponding pads. However, it will be appreciated that fingers 182 may be implemented using other types of structures that facilitate establishment of electrical connections between memory modules and other portions of sockets (e.g., 140) and/or carriers (e.g., 120).

To facilitate establishment of electronic contacts with all of the pads in the dual rows, some fingers of may be greater height than the others (e.g., those towards the outside of interposer 180) to establish electronic contacts with a portion of the pads (e.g., the second row from the edge of the connector). Consequently, these fingers may extend over other fingers used to establish operably connections with other pads (e.g., the first rows on the edge connectors).

Turning to FIG. 8, to establish electrical contacts with a single row of pads, socket 140 may include interposer 180 and fingers 184.

Interposer 180 may include a piece of circuit card or other material usable to route signals from a planar to vertical configuration. For example, posts or other electrical contacts (illustrated in solid black in FIG. 7) may extend downward from interposer 180 and out of a body of socket 140 (e.g., the rectangular outline).

On the surface of interposer 180, any number of fingers 184 may extend upward. Fingers 184 may be metallic structures and may be natively spring loaded and/or loaded by other structures (not shown) to generally press toward a center of socket 140. In FIG. 8, the connector portion of carrier 150 is positioned in socket 140. Consequently, fingers 184 are illustrated as resting on corresponding pads.

To facilitate establishment of electronic contacts with all of the pads in the single row, fingers 184 may be of a same height as the others, and aligned with one another (e.g., into the page).

The number, positioning, and/or other characteristics of the fingers may be adapted to support 1.5 times, 2 times, 2.5 times, 3 times, 3.5 times, or four times (e.g., approximately, within 10%) the bandwidth of the Double Data Rate 5 Synchronous Dynamic Random-Access Memory (DDR5 SDRAM) standard. For example, the number of fingers may be approximately twice that of the number of conductors used by sockets that support the DDR5 SDRAM standard. For example, the fingers (and other aspects of the socket and edge connector) may support approximately 8 gigatransfers per second, 10 gigatransfers per second, 15 gigatransfers per second, 20 gigatransfers per second, 25 gigatransfers per second, or 30 gigatransfers per second. The transfer rate may be between 25 and 35 gigatransfers per second or between 20 and 40 gigatransfers per second.

Thus, using the architecture illustrated in FIGS. 1-8, embodiments disclosed herein may improve the efficiency of use of space in data processing systems. The embodiments may do so by (i) increasing communication bandwidth to memory modules, (ii) logically dividing the memory modules to accommodate independent channel operation, (iii) utilizing stacked or other multi-die memory device architectures to increase memory density, (iv) placing memory devices on multiple sides of carriers, and/or (v) utilizing cooling elements such as head spreaders to manage the increased thermal profiles of memory modules disclosed herein.

To facilitate operation of systems disclosed herein, the components of the data processing system may operate in predetermined manners.

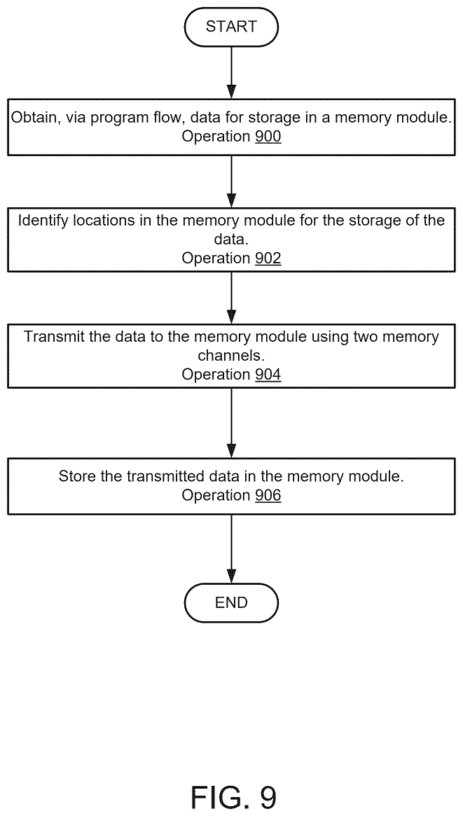

Turning to FIG. 9, a flow diagram illustrating a method for storing data in a memory module in accordance with an embodiment is shown.

At operation 900, data for storage in a memory module may be obtained. The data may be obtained via flow of a program in a processor. The flow of the program may generate the data and request that the data be stored in memory.

At operation 902, locations in the memory module for the storage of the data are identified. The locations may be identified by (i) identifying logical blocks that are unallocated, and (ii) allocating the logical blocks for the data.

To facilitate identification, an operating system or other entity may manage the use of the logical blocks by various applications. The operating system may establish logical block addresses for physical blocks, and may establish an allocation scheme. The program may, as part of its operation, send a request to the operating system for storage of the data. The operating system may, in turn, review records regarding allocated and unallocated blocks. To facilitate improved performance, the operating system may intentionally search for unallocated logical blocks that map to physical blocks in memory devices that are reachable via different memory channels. Once identified, metadata may be stored that indicates that the identified logical blocks are now allocated for storing the data.

At operation 904, the data is transmitted to the memory module using two memory channels. The data may be transmitted by (i) identifying the memory channels, (ii) providing the data to memory controllers (e.g., may be onboard a processor, or may be discrete devices) associated with the respective channels, and (iii) requesting that the provided data be transmitted. The memory controllers may be part of or separate from a processor executing the program.

The memory channels may be identified, for example, using mappings between different logical block addresses and memory channels (e.g., may be stored in a lookup data structure).

Once provided to the memory controllers, the memory controllers may generate electrical signals on which the data is carried to the memory module.

AT operation 906, the transmitted data is stored in the memory module. The transmitted data may be stored by pushing the data to buffers of the memory module until the data can be written to memory devices of the memory module.

The method may end following operation 906.

Thus, using the method illustrated in FIG. 9, embodiments disclosed herein may facilitate data storage.

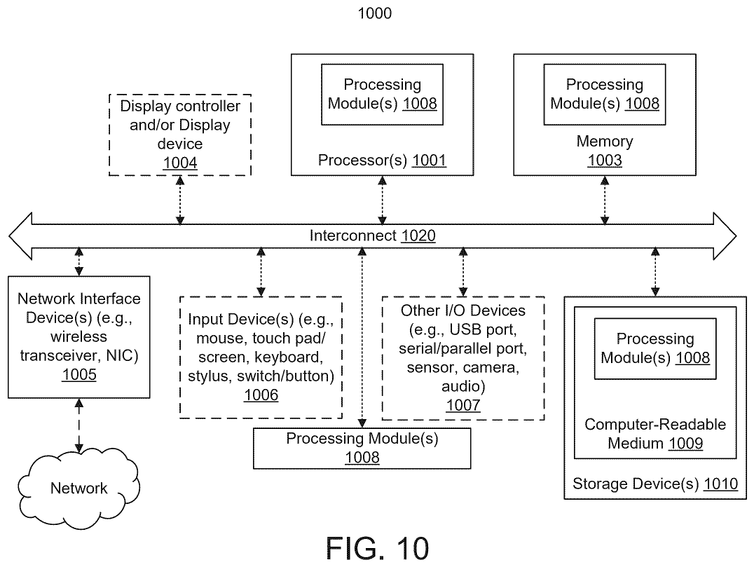

The aforementioned method shown in FIG. 9 and system shown in FIGS. 1-8 may be performed by and be part of a computing device. Turning to FIG. 10, a block diagram illustrating an example of a computing device (e.g., a data processing system) in accordance with an embodiment is shown. For example, system 1000 may represent any of data processing systems described above performing any of the processes or methods described above. System 1000 can include many different components. These components can be implemented as integrated circuits (ICs), portions thereof, discrete electronic devices, or other modules adapted to a circuit board such as a motherboard or add-in card of the computer system, or as components otherwise incorporated within a chassis of the computer system. Note also that system 1000 is intended to show a high level view of many components of the computer system. However, it is to be understood that additional components may be present in certain implementations and furthermore, different arrangement of the components shown may occur in other implementations. System 1000 may represent a desktop, a laptop, a tablet, a server, a mobile phone, a media player, a personal digital assistant (PDA), a personal communicator, a gaming device, a network router or hub, a wireless access point (AP) or repeater, a set-top box, or a combination thereof. Further, while only a single machine or system is illustrated, the term “machine” or “system” shall also be taken to include any collection of machines or systems that individually or jointly execute a set (or multiple sets) of instructions to perform any one or more of the methodologies discussed herein.

In one embodiment, system 1000 includes processor 1001, memory 1003, and devices 1005-1007 via a bus or an interconnect 1020. Processor 1001 may represent a single processor or multiple processors with a single processor core or multiple processor cores included therein. Processor 1001 may represent one or more general-purpose processors such as a microprocessor, a central processing unit (CPU), or the like. More particularly, processor 1001 may be a complex instruction set computing (CISC) microprocessor, reduced instruction set computing (RISC) microprocessor, very long instruction word (VLIW) microprocessor, or processor implementing other instruction sets, or processors implementing a combination of instruction sets. Processor 1001 may also be one or more special-purpose processors such as an application specific integrated circuit (ASIC), a cellular or baseband processor, a field programmable gate array (FPGA), a digital signal processor (DSP), a network processor, a graphics processor, a network processor, a communications processor, a cryptographic processor, a co-processor, an embedded processor, or any other type of logic capable of processing instructions.

Processor 1001, which may be a low power multi-core processor socket such as an ultra-low voltage processor, may act as a main processing unit and central hub for communication with the various components of the system. Such processor can be implemented as a system on chip (SoC). Processor 1001 is configured to execute instructions for performing the operations discussed herein. System 1000 may further include a graphics interface that communicates with optional graphics subsystem 1004, which may include a display controller, a graphics processor, and/or a display device.

Processor 1001 may communicate with memory 1003, which in one embodiment can be implemented via multiple memory devices to provide for a given amount of system memory. Memory 1003 may include one or more volatile storage (or memory) devices such as random access memory (RAM), dynamic RAM (DRAM), synchronous DRAM (SDRAM), static RAM (SRAM), or other types of storage devices. Memory 1003 may store information including sequences of instructions that are executed by processor 1001, or any other device. For example, executable code and/or data of a variety of operating systems, device drivers, firmware (e.g., input output basic system or BIOS), and/or applications can be loaded in memory 1003 and executed by processor 1001. An operating system can be any kind of operating systems, such as, for example, Windows® operating system from Microsoft®, Mac OS®/iOS® from Apple, Android® from Google®, Linux®, Unix®, or other real-time or embedded operating systems such as VxWorks.

System 1000 may further include IO devices such as devices (e.g., 1005, 1006, 1007, 1008) including network interface device(s) 1005, optional input device(s) 1006, and other optional IO device(s) 1007. Network interface device(s) 1005 may include a wireless transceiver and/or a network interface card (NIC). The wireless transceiver may be a WiFi transceiver, an infrared transceiver, a Bluetooth transceiver, a WiMax transceiver, a wireless cellular telephony transceiver, a satellite transceiver (e.g., a global positioning system (GPS) transceiver), or other radio frequency (RF) transceivers, or a combination thereof. The NIC may be an Ethernet card.

Input device(s) 1006 may include a mouse, a touch pad, a touch sensitive screen (which may be integrated with a display device of optional graphics subsystem 1004), a pointer device such as a stylus, and/or a keyboard (e.g., physical keyboard or a virtual keyboard displayed as part of a touch sensitive screen). For example, input device(s) 1006 may include a touch screen controller coupled to a touch screen. The touch screen and touch screen controller can, for example, detect contact and movement or break thereof using any of a plurality of touch sensitivity technologies, including but not limited to capacitive, resistive, infrared, and surface acoustic wave technologies, as well as other proximity sensor arrays or other elements for determining one or more points of contact with the touch screen.

IO devices 1007 may include an audio device. An audio device may include a speaker and/or a microphone to facilitate voice-enabled functions, such as voice recognition, voice replication, digital recording, and/or telephony functions. Other IO devices 1007 may further include universal serial bus (USB) port(s), parallel port(s), serial port(s), a printer, a network interface, a bus bridge (e.g., a PCI-PCI bridge), sensor(s) (e.g., a motion sensor such as an accelerometer, gyroscope, a magnetometer, a light sensor, compass, a proximity sensor, etc.), or a combination thereof. IO device(s) 1007 may further include an imaging processing subsystem (e.g., a camera), which may include an optical sensor, such as a charged coupled device (CCD) or a complementary metal-oxide semiconductor (CMOS) optical sensor, utilized to facilitate camera functions, such as recording photographs and video clips. Certain sensors may be coupled to interconnect 1020 via a sensor hub (not shown), while other devices such as a keyboard or thermal sensor may be controlled by an embedded controller (not shown), dependent upon the specific configuration or design of system 1000.

To provide for persistent storage of information such as data, applications, one or more operating systems and so forth, a mass storage (not shown) may also couple to processor 1001. In various embodiments, to enable a thinner and lighter system design as well as to improve system responsiveness, this mass storage may be implemented via a solid state device (SSD). However, in other embodiments, the mass storage may primarily be implemented using a hard disk drive (HDD) with a smaller amount of SSD storage to act as an SSD cache to enable non-volatile storage of context state and other such information during power down events so that a fast power up can occur on re-initiation of system activities. Also a flash device may be coupled to processor 1001, e.g., via a serial peripheral interface (SPI). This flash device may provide for non-volatile storage of system software, including a basic input/output software (BIOS) as well as other firmware of the system.

Storage device 1010 may include computer-readable storage medium 1009 (also known as a machine-readable storage medium or a computer-readable medium) on which is stored one or more sets of instructions or software (e.g., processing module, unit, and/or processing module/unit/logic 1008) embodying any one or more of the methodologies or functions described herein. Processing module/unit/logic 1008 may represent any of the components described above. Processing module/unit/logic 1008 may also reside, completely or at least partially, within memory 1003 and/or within processor 1001 during execution thereof by system 1000, memory 1003 and processor 1001 also constituting machine-accessible storage media. Processing module/unit/logic 1008 may further be transmitted or received over a network via network interface device(s) 1005.

Computer-readable storage medium 1009 may also be used to store some software functionalities described above persistently. While computer-readable storage medium 1009 is shown in an exemplary embodiment to be a single medium, the term “computer-readable storage medium” should be taken to include a single medium or multiple media (e.g., a centralized or distributed database, and/or associated caches and servers) that store the one or more sets of instructions. The terms “computer-readable storage medium” shall also be taken to include any medium that is capable of storing or encoding a set of instructions for execution by the machine and that cause the machine to perform any one or more of the methodologies of embodiments disclosed herein. The term “computer-readable storage medium” shall accordingly be taken to include, but not be limited to, solid-state memories, and optical and magnetic media, or any other non-transitory machine-readable medium.

Processing module/unit/logic 1008, components and other features described herein can be implemented as discrete hardware components or integrated in the functionality of hardware components such as ASICS, FPGAs, DSPs or similar devices. In addition, processing module/unit/logic 1008 can be implemented as firmware or functional circuitry within hardware devices. Further, processing module/unit/logic 1008 can be implemented in any combination hardware devices and software components.

Note that while system 1000 is illustrated with various components of a data processing system, it is not intended to represent any particular architecture or manner of interconnecting the components; as such details are not germane to embodiments disclosed herein. It will also be appreciated that network computers, handheld computers, mobile phones, servers, and/or other data processing systems which have fewer components or perhaps more components may also be used with embodiments disclosed herein.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities.

It should be borne in mind, however, that all of these and similar terms are to be associated with the appropriate physical quantities and are merely convenient labels applied to these quantities. Unless specifically stated otherwise as apparent from the above discussion, it is appreciated that throughout the description, discussions utilizing terms such as those set forth in the claims below, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Embodiments disclosed herein also relate to an apparatus for performing the operations herein. Such a computer program is stored in a non-transitory computer readable medium. A non-transitory machine-readable medium includes any mechanism for storing information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices).

The processes or methods depicted in the preceding figures may be performed by processing logic that comprises hardware (e.g. circuitry, dedicated logic, etc.), software (e.g., embodied on a non-transitory computer readable medium), or a combination of both. Although the processes or methods are described above in terms of some sequential operations, it should be appreciated that some of the operations described may be performed in a different order. Moreover, some operations may be performed in parallel rather than sequentially.

Embodiments disclosed herein are not described with reference to any particular programming language. It will be appreciated that a variety of programming languages may be used to implement the teachings of embodiments disclosed herein.

In the foregoing specification, embodiments have been described with reference to specific exemplary embodiments thereof. It will be evident that various modifications may be made thereto without departing from the broader spirit and scope of the embodiments disclosed herein as set forth in the following claims. The specification and drawings are, accordingly, to be regarded in an illustrative sense rather than a restrictive sense.

What is claimed is:

1. A data processing system, comprising:
a processor;
a memory module; and
a circuit board comprising:
a first socket for the processor;
a second socket for the memory module;
a first physical memory channel interconnecting a first portion of the first socket and a first portion of the second socket; and
a second physical memory channel interconnecting a second portion of the first socket and a second portion of the second socket.

2. The data processing system of claim 1, wherein the first physical memory channel and the second physical memory channel are exclusively used by devices positioned in the second socket.

3. The data processing system of claim 1, wherein the second socket comprises:
an interposer; and
a plurality of high density fingers adapted to establish electrical contacts with pads of the memory module.

4. The data processing system of claim 3, wherein the plurality of high density fingers are adapted to establish the electrical contacts with the pads in a dual row configuration.

5. The data processing system of claim 3, wherein the plurality of high density fingers are adapted to establish the electrical contacts with the pads in a single row configuration.

6. The data processing system of claim 3, wherein the plurality of high density fingers are adapted to support at least 25 gigatransfers per second.

7. The data processing system of claim 3, wherein the plurality of high density fingers are adapted to support a bandwidth of approximately quadruple that of the Double Data Rate 5 Synchronous Dynamic Random-Access Memory standard.

8. The data processing system of claim 1, wherein the memory module comprises:
a carrier comprising:
an edge connector comprising:
a first portion adapted to operably connect to the first portion of the second socket; and
a second portion adapted to operably connect to the second portion of the socket.

9. The data processing system of claim 8, wherein the memory module further comprises:
a first set of memory devices operably connected to the first portion of the edge connector; and
a second set of memory devices operably connected to the second portion of the edge connector.

10. The data processing system of claim 9, wherein each memory device of the first set of memory devices is a multi-die memory device.

11. The data processing system of claim 10, wherein the first set of memory devices is distributed across two sides of the carrier.

12. The data processing system of claim 9, wherein the memory module further comprises:
a signal buffer logic adapted to independently manage the first set of memory devices and independently manage the second set of memory devices.

13. The data processing system of claim 12, wherein independently managing the first set of memory devices comprises:
participating in training of a first logical memory channel for the first physical memory channel, the training of the first logical memory channel identifying a communication speed for the first logical memory channel.

14. The data processing system of claim 1, wherein the first physical memory channel comprises a set of traces positioned on the circuit board.

15. A circuit board, comprising:
a first socket for a processor;
a second socket for a memory module;
a first physical memory channel interconnecting a first portion of the first socket and a first portion of the second socket; and
a second physical memory channel interconnecting a second portion of the first socket and a second portion of the second socket.

16. The circuit board of claim 15, wherein the first physical memory channel and the second physical memory channel are exclusively used by devices positioned in the second socket.

17. The circuit board of claim 15, wherein the second socket comprises:
an interposer; and
a plurality of high density fingers adapted to establish electrical contacts with pads of the memory module.

18. The circuit board of claim 17, wherein the plurality of high density fingers are adapted to establish the electrical contacts with the pads in a dual row configuration.

19. The circuit board of claim 17, wherein the plurality of high density fingers are adapted to establish the electrical contacts with the pads in a single row configuration.

20. The circuit board of claim 17, wherein the plurality of high density fingers are adapted to support at least 25 gigatransfers per second.
